(19) United States
(12) Patent Application Publication
(10) Pub. No.: US 2026/0334291 A1
(43) Pub. Date: Oct. 22, 2026

(54) SEMICONDUCTOR PACKAGE INCLUDING GAP FILLING LAYER

(71) Applicant: Samsung Electronics Co., Ltd., Suwon-si (KR)

(72) Inventors: Kyungdon MUN, Suwon-si (KR); Sangjin BAEK, Suwon-si (KR); Junhyeong LEE, Suwon-si (KR); Sehoon JANG, Suwon-si (KR)

(73) Assignee: Samsung Electronics Co., Ltd., Suwon-si (KR)

(21) Appl. No.: 19/351,432

(22) Filed: Oct. 7, 2025

(30) Foreign Application Priority Data
Apr. 21, 2025 (KR) 10-2025-0051608

(51) Int. Cl. H01L 23/31; H01L 23/00; H01L 23/29; H01L 23/373; H01L 23/498; H01L 23/538; H01L 25/10

(52) U.S. Cl. CPC H10W 74/121; H10W 40/251; H10W 70/611; H10W 74/476; H10W 90/00; H10W 90/401; H10W 90/701; H10W 72/50; H10W 72/884; H10W 74/15; H10W 90/724; H10W 90/732; H10W 90/734

(57) ABSTRACT

A semiconductor package according to some example embodiments of the present disclosure includes: a first redistribution structure; a first semiconductor chip structure on the first redistribution structure; a second redistribution structure on the first semiconductor chip structure; a second semiconductor chip structure on the second redistribution structure; a first filling layer between the second redistribution structure and the second semiconductor chip structure; a heat dissipation member on the second redistribution structure and spaced apart from the second semiconductor chip structure in a first direction; and a gap filling layer between the second semiconductor chip structure and the heat dissipation member, and the first filling layer and the gap filling layer include different materials.

### CROSS-REFERENCE TO RELATED APPLICATION(S)

This application claims benefit of priority to Korean Patent Application No. 10-2025-0051608 filed on Apr. 21, 2025, in the Korean Intellectual Property Office, the disclosure of which is incorporated herein by reference in its entirety.

### BACKGROUND

The present disclosure relates to a semiconductor package including a gap filling layer

As electronic devices become more high-performance and highly integrated, the development of high-performance and highly integrated semiconductor chips may be required. Accordingly, the importance of semiconductor package technology that may protect semiconductor chips, effectively dissipate heat, and stably transmit electrical signals has increased. Since warpage may occur in the manufacturing process of semiconductor packages and may cause poor electrical connection and reduced heat dissipation, limiting and/or preventing warpage may be advantageous to secure electrical stability and reliability of semiconductor packages.

### SUMMARY

An aspect of the present disclosure is to provide a semiconductor package having improved electrical stability and reliability.

According to some example embodiments of the present disclosure, a semiconductor package may include a first redistribution structure; a first semiconductor chip structure on the first redistribution structure; a second redistribution structure on the first semiconductor chip structure; a second semiconductor chip structure on the second redistribution structure; a first filling layer between the second redistribution structure and the second semiconductor chip structure; a heat dissipation member on the second redistribution structure, wherein the heat dissipation member may be spaced apart from the second semiconductor chip structure in a first direction; and a gap filling layer between the second semiconductor chip structure and the heat dissipation member, wherein a material of the first filling layer may be different from a material of the gap filling layer.

According to some example embodiments of the present disclosure, a semiconductor package may include a first redistribution structure including a first insulating layer and a first redistribution layer in the first insulating layer; a first semiconductor package on the first redistribution structure and including a first semiconductor chip structure and a second redistribution structure on the first semiconductor chip structure; a second semiconductor package on the second redistribution structure and including a second semiconductor chip structure; a heat dissipation member on the second redistribution structure and spaced apart from the second semiconductor package in a first direction; a gap filling layer between the second semiconductor package and the heat dissipation member; a first bonding material layer extending from a first region of the second redistribution structure, the first bonding material layer contacting a lower surface of the heat dissipation member; and a second bonding material layer extending from a second region of the second redistribution structure, the second bonding material layer contacting the lower surface of the heat dissipation member, wherein an elastic modulus of the first bonding material layer may be different from an elastic modulus of the second bonding material layer.

According to some example embodiments of the present disclosure, a semiconductor package may include a first redistribution structure including a first insulating layer and a first redistribution layer in the first insulating layer; a first semiconductor chip structure on the first redistribution structure and including a first semiconductor chip; an external connection bump below the first redistribution structure and connected to the first redistribution layer; a first encapsulant on the first redistribution structure and covering the first semiconductor chip structure; a second redistribution structure on the first encapsulant, the second redistribution structure including a second insulating layer and a second redistribution layer in the second insulating layer; an interconnect structure penetrating through the first encapsulant and electrically connecting the first redistribution layer and the second redistribution layer; a second semiconductor chip structure on the second redistribution structure and including a second semiconductor chip; a second encapsulating material covering the second semiconductor chip structure; a redistribution substrate below the second semiconductor chip structure; a heat dissipation member on the second redistribution structure and spaced apart from the second semiconductor chip structure in a first direction; a plurality of first bonding members below the redistribution substrate and spaced apart from each other in the first direction; a plurality of second bonding members below the heat dissipation member and spaced apart from each other in the first direction; a first filling layer below the redistribution substrate on the second redistribution structure and covering the plurality of first bonding members; a second filling layer below the heat dissipation member on the second redistribution structure and covering the plurality of second bonding members; and a gap filling layer between the second semiconductor chip structure and the heat dissipation member, wherein a material in the gap filling layer may be different from a material in the first filling layer and a material in the second filling layer, and wherein a material of the plurality of second bonding members may be different from the material of the second filling layer.

According to some example embodiments of the present disclosure, a gap filling layer may be disposed in a gap region formed between a second semiconductor package and a heat dissipation structure, warpage of the semiconductor package may be limited and/or prevented. Accordingly, a semiconductor package having improved electrical stability and reliability may be provided.

Advantages and effects of the present application are not limited to the foregoing content and may be more easily understood in the process of describing a specific example embodiment of the present disclosure.

### BRIEF DESCRIPTION OF DRAWINGS

The above and other aspects, features, and advantages of the present disclosure will be more clearly understood from the following detailed description, taken in conjunction with the accompanying views, in which:

FIG. 1 is a plan view illustrating a semiconductor package according to some embodiment examples of the present disclosure;

FIG. 2 is a cross-sectional view taken along line I-I′ of FIG. 1;

FIG. 3 is a plan view illustrating a semiconductor package according to some example embodiments of the present disclosure;

FIG. 4 is a cross-sectional view taken along line II-II′ of FIG. 3;

FIG. 5 is a plan view illustrating a semiconductor package according to some example embodiments of the present disclosure;

FIG. 6 is a cross-sectional view taken along line III-III′ of FIG. 5;

FIGS. 7 to 26 are intermediate operation views illustrating a method of manufacturing a semiconductor package according to some example embodiments of the present disclosure; and

FIG. 27 is a block diagram schematically illustrating an electronic device including a semiconductor package according to some example embodiments of the present disclosure.

### DETAILED DESCRIPTION

Hereinafter, example embodiments of the present disclosure will be described with reference to the accompanying views. In order to clearly explain the present disclosure, portions not related to the explanation are omitted, and the same reference numerals are used for identical or similar components throughout the specification.

When an element, a component, a layer, a pattern, a structure, a region, or the like, (hereinafter collectively referred to as a “component”) of the present disclosure is referred to as being “over,” “above,” “on,” “below,” “under,” “beneath,” “connected to,” or “coupled to or combined to” another component, it may be directly over, above, on, below, under, beneath, connected to, or coupled to or combined to another component, or intermediate components may be present between components. In contrast, when one component of the present disclosure is referred to as being “directly over,” “directly above,” “directly on,” “directly below,” “directly under,” “directly beneath,” “directly beneath,” “directly connected to,” or “directly coupled to or directly combined to” another component of the present disclosure, there are no intermediate components.

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

In this disclosure, although the terms such as first, second, and the like, are used to describe various components, these components are not limited by these terms. It should be understood that these terms are used only to distinguish one component from another component.

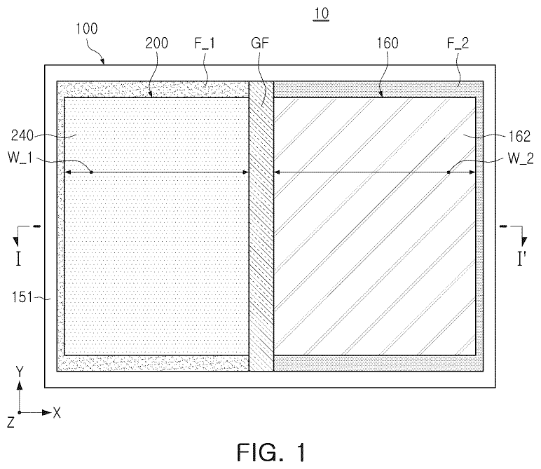

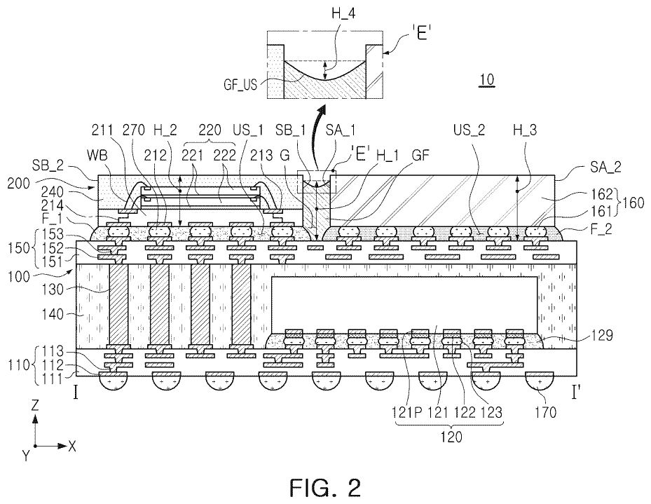

FIG. 1 is a plan view illustrating a semiconductor package according to some example embodiments of the present disclosure. FIG. 2 is a cross-sectional view taken along line I-I′ of FIG. 1. Referring to FIGS. 1 and 2, a semiconductor package 10 according to some example embodiments of the present disclosure may include a first semiconductor package 100, a second semiconductor package 200, and a heat dissipation structure 160. The second semiconductor package 200 may be disposed on the first semiconductor package 100. The heat dissipation structure 160 may be spaced apart from the second semiconductor package 200 in a first direction (e.g., X-direction). The second semiconductor package 200 and the heat dissipation structure 160 may be spaced apart from each other in the first direction (e.g., X-direction), so that a gap region G may be formed between the second semiconductor package 200 and the heat dissipation structure 160. The semiconductor package 10 according to some example embodiments of the present disclosure may be manufactured using a Fan-Out Wafer-Level Packaging (FOWLP) process. However, the present disclosure is not limited thereto. For example, the semiconductor package 10 according to some example embodiments of the present disclosure may also be manufactured using a Fan-Out Panel-Level Packaging (FOPLP) process.

The first semiconductor package 100 may include a first redistribution structure 110, a first semiconductor chip structure 120, an interconnect structure 130, a first encapsulant 140, a second redistribution structure 150, and a plurality of external connection bumps 170. The second semiconductor package 200 may include a redistribution substrate 211, a second semiconductor chip structure 220, and a second encapsulant 240. The first semiconductor package 100 may be referred to as a lower semiconductor package 100 or a first semiconductor package 100. The second semiconductor package 200 disposed on the first semiconductor package 100 may be referred to as an upper semiconductor package 200 or a second semiconductor package 200.

The first redistribution structure 110 may include a first insulating layer 111, a plurality of first redistribution layers 112, and a plurality of first redistribution vias 113. The first redistribution structure 110 may be a support substrate on which the first semiconductor chip structure 120 is mounted.

The first insulating layer 111 may include an insulating resin. The insulating resin may include a thermosetting resin such as an epoxy resin, a thermoplastic resin such as a polyimide. For example, the insulating resin may further include prepreg, Ajinomoto Build-up Film (ABF), FR-4, or Bismaleimide-Triazine (BT), etc., which may be obtained by impregnating an inorganic filler into the thermosetting resin or the thermoplastic resin. In some example embodiments, the first insulating layer 111 may include a photosensitive resin such as Photo-Imageable Dielectric (PID). Although not illustrated, the first insulating layer 111 may include a plurality of insulating layers stacked in a second direction (e.g., Z-direction), intersecting the first direction (e.g., X-direction). Boundaries between the plurality of insulating layers may be unclear.

The first redistribution layer 112 may be disposed on the first insulating layer 111. Additionally, the first redistribution layer 112 may be disposed within the first insulating layer 111. The first redistribution layer 112 may redistribute a connection terminal 121P of the first semiconductor chip structure 120. The first redistribution layer 112 may be electrically connected to one or more connection terminals 121P of the first semiconductor chip structure 120. The first redistribution layer 112 may include a metal including copper (Cu), aluminum (Al), silver (Ag), tin (Sn), gold (Au), nickel (Ni), lead (Pb), titanium (Ti), or alloys thereof.

The first redistribution layer 112 may perform various functions depending on the design. For example, the first redistribution layer 112 may include a ground (GrouND: GND) pattern, a power (PoWeR: PWR) pattern, and/or a signal (Signal: S) pattern. Here, the signal pattern may be defined as a transmission path of various signals, such as a data signal, excluding the ground pattern, the power pattern, and the like. The plurality of first redistribution layers 112 may include more or fewer redistribution layers than those illustrated in the drawing. A plurality of first redistribution layers 112 disposed on an upper surface of the first insulating layer 111 may be electrically connected to a plurality of interconnect structures 130 and a plurality of connection terminals 121P of the first semiconductor chip structure 120.

The first redistribution via 113 may extend in the second direction (e.g., Z-direction) within the first insulating layer 111 and may be electrically connected to the first redistribution layer 112. For example, the first redistribution via 113 may interconnect a plurality of first redistribution layers 112 disposed on different levels. The plurality of first redistribution vias 113 may include a signal via, a ground via, and a power via. For example, the first redistribution via 113 may include a metallic material including copper (Cu), aluminum (Al), silver (Ag), tin (Sn), gold (Au), nickel (Ni), lead (Pb), titanium (Ti), or alloys thereof. The first redistribution via 113 may be a filled via in which the metallic material is filled inside a via hole or a conformal via in which a metallic material extends along an inner wall of the via hole.

The first semiconductor chip structure 120 may be disposed on the first redistribution structure 110. The first semiconductor chip structure 120 may include a first semiconductor chip 121, at least one connection terminal 121P, at least one connection pillar 122, and at least one connection solder 123. The first semiconductor chip 121 may be disposed on the first redistribution structure 110. For example, the first semiconductor chip 121 may be disposed on an upper surface of the first redistribution structure 110. The first semiconductor chip 121 may include a connection terminal 121P electrically connected to the first redistribution layer 112. For example, a plurality of connection terminals 121P may be connected to a plurality of first redistribution layers 112. The first semiconductor chip 121 may be referred to as the first semiconductor chip 121 or the lower semiconductor chip 121.

The first semiconductor chip 121 may include a semiconductor wafer and a semiconductor wafer integrated circuit (IC) comprised of a semiconductor element such as silicon, germanium, or a compound semiconductor such as silicon carbide (SiC), gallium arsenide (GaAs), indium arsenide (InAs), and indium phosphide (InP). The first semiconductor chip 121 may be a bare semiconductor chip in which a separate bump or a separate interconnection layer is not formed, but the present disclosure is not limited thereto, and the first semiconductor chip 121 may also be a packaged type semiconductor chip. The integrated circuit may be a logic circuit (or ‘logic chip’) such as a central processing unit (CPU), a graphics processing unit (GPU), a field programmable gate array (FPGA), an application processor (AP), a digital signal processor, an encryption processor, a microprocessor, a microcontroller, an analog-to-digital converter, and an application-specific IC (ASIC), or a memory circuit (or ‘memory chip’) including a volatile memory such as a DRAM (dynamic RAM) and a SRAM (static RAM), or a non-volatile memory such as a phase change RAM (PRAM), a magnetic RAM (MRAM), a resistive RAM (RRAM), and a flash memory.

The first semiconductor chip structure 120 may further include a connection pillar 122 and a connection solder 123 connecting the connection terminal 121P to the first redistribution layer 112. An underfill layer 129 may be further disposed between the first semiconductor chip 121 and the first redistribution structure 110. The underfill layer 129 may have a capillary underfill (CUF) structure, but the present disclosure is not limited thereto. According to an example embodiment, the underfill layer 129 may have a molded underfill (MUF) structure integrated with the first encapsulant 140. The connection pillar 122, connection solder 123, and connection terminal 121P of the first semiconductor chip 120 may be provided in plural, where each connection terminal 121P may be connected to a lower surface of the first semiconductor chip 121P and connected to a corresponding connection solder 123 by a corresponding connection pillar 122 connected to the first redistribution layer 112.

The interconnect structure 130 may electrically connect the first redistribution structure 110 and the second redistribution structure 150 by penetrating through the first encapsulant 140. For example, the interconnect structure 130 may electrically connect the first redistribution layer 112 and a second redistribution layer 152. The interconnect structure 130 may extend in the second direction (e.g., Z-direction) within the first encapsulant 140. An upper surface of the interconnect structure 130 may be exposed from the first encapsulant 140 and may be coplanar with an upper surface of the first encapsulant 140. For example, the interconnect structure 130 may have a post shape penetrating through the first encapsulant 140. However, the shape of the interconnect structure 130 is not limited thereto. The interconnect structure 130 may include a metallic material such as copper (Cu). According to an example embodiment, a metal seed layer including titanium (Ti), copper (Cu), or the like may be formed on a lower surface of the interconnect structure 130. In some example embodiments, the interconnect structure 130 may not overlap the heat dissipation structure 160 in the second direction (e.g., Z-direction), intersecting the first direction (e.g., X-direction). Such an arrangement of the interconnect structure 130 may improve the integration density of the semiconductor package 10. The interconnect structure 130 may be provided in plurality so a plurality of interconnect structures 130 may be spaced apart from each other in the first encapsulant 140.

The first encapsulant 140 may be disposed on the first redistribution structure 110 and may cover the first semiconductor chip structure 120. For example, the first encapsulant 140 may encapsulate at least a portion of the first semiconductor chip structure 120 on the first redistribution structure 110. For example, the first encapsulant 140 may include a thermosetting resin such as an epoxy resin or a thermoplastic resin such as a polyimide. For example, the first encapsulant 140 may further include prepreg, ABF, FR-4, BT and Epoxy Molding Compound (EMC), etc., in which an inorganic filler is impregnated into the thermosetting resin or the thermoplastic resin. That is, the first encapsulant 140 may include EMC.

The second redistribution structure 150 may be disposed on the first semiconductor chip structure 120 and the first encapsulant 140. The second redistribution structure 150 may include a second insulating layer 151, a plurality of second redistribution layers 152, and a plurality of second redistribution vias 153.

The second insulating layer 151 may be disposed on the first semiconductor chip structure 120 and the first encapsulant 140. The second insulating layer 151 may be referred to as a second insulating layer 151 or an upper insulating layer 151. The second insulating layer 151 may include an insulating resin. The insulating resin may include a thermosetting resin such as an epoxy resin or a thermoplastic resin such as a polyimide. For example, the insulating resin may further include prepreg, ABF, FR-4, BT, PID, etc., which may be obtained by impregnating an inorganic filler into the thermosetting resin or the thermoplastic resin. The second insulating layer 151 may include a plurality of layers stacked in the second direction (e.g., Z-direction). Depending on the process, the boundaries between the plurality of layers may be unclear.

The second redistribution layer 152 may be disposed on the second insulating layer 151. Additionally, the second redistribution layer 152 may be disposed within the second insulating layer 151. The second redistribution layer 152 may redistribute the interconnect structure 130. The second redistribution layer 152 disposed on the second insulating layer 151 may be referred to as an uppermost second redistribution layer 152. For example, the second redistribution layer 152 may include a metallic material including copper (Cu), aluminum (Al), silver (Ag), tin (Sn), gold (Au), nickel (Ni), lead (Pb), titanium (Ti), or alloys thereof. The plurality of second redistribution layers 152 may include more or fewer redistribution layers than those illustrated in the drawing.

The second redistribution layer 152 may be disposed on an upper surface of the second redistribution structure 150. Here, the second redistribution layer 152 may be physically and electrically connected to an external device. Although not illustrated, a barrier layer may be further disposed on a surface of the second redistribution layer 152 on the second insulating layer 151 according to some example embodiments.

The second redistribution via 153 may be electrically connected to the second redistribution layer 152 by penetrating through the second insulating layer 151. For example, a plurality of second redistribution vias 153 may interconnect a plurality of second redistribution layers 152 disposed on different levels. The second redistribution via 153 may be a filled via in which a metallic material is filled inside a via hole or a conformal via in which a metallic material extends along an inner wall of a via hole.

The plurality of external connection bumps 170 may be disposed below the first redistribution structure 110. The external connection bumps 170 may be electrically connected to the first semiconductor chip 121 and the interconnect structure 130 through the first redistribution layer 112. The semiconductor package 10 may be connected to an external device, such as a module substrate or a system board, through the external connection bumps 170. For example, the external connection bumps 170 may include a low melting point metal. Specifically, the external connection bumps 170 may include tin (Sn) or alloys (Sn-Ag-Cu) including tin (Sn). In some example embodiments, the external connection bumps 170 may have a shape in which a pillar (or underbump metal) and a ball are combined. The pillar may include copper (Cu) or alloys of copper (Cu), and the ball may include a solder ball. In some example embodiments, the first insulating layer 111 may further include a resist layer for protecting the external connection bump 170 from external physical and chemical damage.

The second semiconductor package 200 may be disposed on the first semiconductor package 100. For example, the second semiconductor package 200 may be disposed on the second redistribution structure 150 of the first semiconductor package 100. The second semiconductor package 200 may be spaced apart from the heat dissipation structure 160 in the first direction (e.g., X-direction). In some example embodiments, the second semiconductor package 200 may extend in the third direction (e.g., Y-direction), intersecting each of the first direction (e.g., X-direction) and the second direction (e.g., Z-direction). The second semiconductor package 200 may include the redistribution substrate 211, the second semiconductor chip structure 220, the second encapsulant 240, and a plurality of first bonding members 270.

The redistribution substrate 211 may be disposed below the second semiconductor chip structure 220. The redistribution substrate 211 may include a lower pad 212 and an upper pad 213 that may be electrically connected to the outside on a lower surface and an upper surface thereof, respectively. Additionally, the redistribution substrate 211 may include a redistribution circuit 214 electrically connecting the lower pad 212 and the upper pad 213. The redistribution substrate 211 may be a substrate on which the second semiconductor chip structure 220 is mounted.

The second semiconductor chip structure 220 may be mounted on the redistribution substrate 211 by a wire bonding or flip-chip bonding manner. The second semiconductor chip structure 220 may include a plurality of second semiconductor chips 222 stacked vertically. For example, the plurality of second semiconductor chips 222 may be stacked in the second direction (e.g., Z-direction) on the redistribution substrate 211, and may be electrically connected to the upper pad 213 of the redistribution substrate 211 by a bonding wire WB. Although not illustrated, the second semiconductor chip structure 220 may also be mounted on the redistribution substrate 211 by a silicon through-electrode manner. For example, the plurality of second semiconductor chips 222 may be stacked in the second direction (e.g., Z-direction) on the redistribution substrate 211, and may be electrically connected to the upper pad 213 of the redistribution substrate 211 by a silicon through-electrode penetrating through the plurality of second semiconductor chips 222. The second semiconductor chip structure 220 may include a bonding film 221 disposed between the plurality of second semiconductor chips 222 or between the second semiconductor chip 222 and the redistribution substrate 211. In some example embodiments, the second semiconductor chip 222 of the semiconductor package 10 may include a DDR, HBM, or NAND flash memory chip, and the first semiconductor chip 121 may include an AP chip.

The redistribution substrate 211, the lower pad 212, the upper pad 213 and the redistribution circuit 214 may have the characteristics identical to or similar to the first redistribution structure 110. For example, the redistribution substrate 211 may include a ground (GrouND: GND) pattern, a power (PoWeR: PWR) pattern, and a signal (Signal: S) pattern. Here, the signal pattern may be defined as a transmission path of various signals, such as a data signal, excluding the ground pattern, the power pattern, and the like.

The second encapsulant 240 may cover the second semiconductor chip structure 220. For example, the second encapsulant 240 may encapsulate at least a portion of the second semiconductor chip structure 220 on the redistribution substrate 211. The second encapsulant 240 may have the characteristics identical to or similar to the first encapsulant 140. For example, the second encapsulant 240 may include a thermosetting resin such as an epoxy resin, or a thermoplastic resin such as a polyimide. For example, the second encapsulant 240 may further include prepreg, ABF, FR-4, BT and Epoxy Molding Compound (EMC), in which an inorganic filler is impregnated into the thermosetting resin or the thermoplastic resin. That is, the second encapsulant 240 may include EMC.

The second semiconductor package 200 may have a first surface SB_1 and a second side surface SB_2. For example, the second encapsulant 240 of the second semiconductor package 200 may have the first surface SB_1 and the second side surface SB_2. The first surface SB_1 of the second semiconductor package 200 may face a first side surface SA_1 of the heat dissipation structure 160. Specifically, the first surface SB_1 of the second encapsulant 240 may face the first side surface SA_1 of a heat dissipation member 162. Alternatively, the first surface SB_1 of the second encapsulant 240 may be adjacent to the first side surface SA_1 of the heat dissipation member 162.

A plurality of first bonding members 270 may be disposed below the second semiconductor chip structure 220 on the second redistribution structure 150. Alternatively, the plurality of first bonding members 270 may be disposed below the redistribution substrate 211. The plurality of first bonding members 270 may be spaced apart from each other in the first direction (e.g., X-direction). Here, a first lower space US_1 may be formed between the plurality of first bonding members 270. For example, the first lower space US_1 may refer to a lower space formed between the second redistribution structure 150 and the second semiconductor chip structure 220. Alternatively, the first lower space US_1 may refer to a lower space formed between the second redistribution structure 150 and the redistribution substrate 211. Each of the plurality of first bonding members 270 may be in contact with the redistribution substrate 211. The plurality of first bonding members 270 may be connected to the plurality of second redistribution layers 152 on the second insulating layer 151. For example, the plurality of first bonding members 270 may be electrically connected to the plurality of second redistribution layers 152. The plurality of first bonding members 270 may have any number or arrangement. In some example embodiments, the plurality of first bonding members 270 may include a low melting point metal. For example, the plurality of first bonding members 270 may include tin (Sn) or alloys including tin (Sn) (Sn-Ag-Cu). The plurality of first bonding members 270 may have a form in which a pillar (or underbump metal) and a ball are combined. The pillar may include copper (Cu) or alloys of copper (Cu), and the ball may include a solder ball.

The heat dissipation structure 160 may be disposed on the second redistribution structure 150. The heat dissipation structure 160 may be mounted on the first semiconductor package 100. The heat dissipation structure 160 may be spaced apart from the second semiconductor package 200 in the first direction (e.g., X-direction). In some example embodiments, a width W_1 of the second semiconductor package 200 in the first direction (e.g., X-direction) may be greater than a width W_2 of the heat dissipation structure 160 in the first direction (e.g., X-direction). The heat dissipation structure 160 may include a plurality of second bonding members 161 and the heat dissipation member 162.

The plurality of second bonding members 161 may be disposed below the heat dissipation member 162 on the second redistribution structure 150. The plurality of second bonding members 161 may be spaced apart from each other in a first direction (e.g., X-direction). Here, a second lower space US_2 may be formed between the plurality of second bonding members 161. For example, the second lower space US_2 may refer to a lower space formed between the second redistribution structure 150 and the heat dissipation member 162. A plurality of second lower spaces US_2 may be formed between the plurality of second bonding members 161, respectively. Each of the plurality of second bonding members 161 may be in contact with the heat dissipation member 162. The plurality of second bonding members 161 may be in contact with the second insulating layer 151 disposed on the upper surface of the second redistribution structure 150. However, the plurality of second bonding members 161 may not be electrically connected to the remaining components of the semiconductor package 10. For example, the plurality of second bonding members 161 may not be electrically connected to the first semiconductor package 100 and the second semiconductor package 200. Additionally, the plurality of second bonding members 161 may not be electrically connected to an external electronic device, such as a motherboard. The plurality of second bonding members 161 may include a conductive material, such as tin, lead, silver, or alloys thereof. The plurality of second bonding members 161 may have any number or arrangement. In some example embodiments, the plurality of second bonding members 161 may include a low melting point metal. For example, the plurality of second bonding members 161 may include tin (Sn) or alloys including tin (Sn) (Sn-Ag-Cu). The plurality of second bonding members 161 may have a form in which a pillar (or underbump metal) and a ball are combined. The pillar may include copper (Cu) or alloys of copper (Cu), and the ball may include a solder ball. In some example embodiments, the second bonding member 161 may improve warpage of the semiconductor package 10. For example, the second bonding member 161 may disperse stress caused by a difference in coefficient of thermal expansion (CTE) between upper and lower components of the semiconductor package 10. Additionally, the second bonding member 161 may be strongly bonded to the second redistribution structure 150 to perform a buffering action against stress generated in a process of manufacturing the semiconductor package 10. Accordingly, the structural stability of the semiconductor package 10 may be improved, and a warpage phenomenon may be improved.

The heat dissipation member 162 may be disposed on the second redistribution structure 150. The heat dissipation member 162 may be disposed on at least one side of the second semiconductor package 200. For example, the heat dissipation member 162 may be spaced apart from the second semiconductor package 200 in the first direction (e.g., X-direction). The heat dissipation member 162 may be disposed on a plurality of first bonding members 161. That is, the plurality of first bonding members 161 may be disposed between the heat dissipation member 162 and the second redistribution structure 150. The heat dissipation member 162 may have a first side surface SA_1 and a second side surface SA_2. The first side surface SA_1 may face the first surface SB_1 of the second semiconductor package 200. In some example embodiments, the heat dissipation member 162 may discharge heat generated by the first semiconductor package 100 to the outside. For example, the first semiconductor package 100 may include a semiconductor device such as a CPU or a GPU. The heat dissipation member 162 may discharge the heat generated by the semiconductor device of the first semiconductor package 100 to the outside. Accordingly, the electrical stability and reliability of the semiconductor package 10 may be improved. The heat dissipation member 162 may include a material having excellent thermal conductivity. In some example embodiments, the heat dissipation member 162 may further include silicon (Si). Accordingly, the heat dissipation member 162 and the plurality of second bonding members 161 may be more easily connected or coupled.

The semiconductor package 10 may include a first filling layer F_1, a second filling layer F_2, and a gap filling layer GF. The first filling layer F_1 may be disposed between the second redistribution structure 150 and the second semiconductor chip structure 220. The first filling layer F_1 may be disposed between the redistribution substrate 211 and the redistribution structure 150. The first filling layer F_1 may fill the first lower space US_1 formed between the plurality of first bonding members 270. The first filling layer F_1 may cover the plurality of first bonding members 270. The first filling layer F_1 may include a first resin-based material. Here, the first resin-based material may refer to a pure resin-based material that does not include a thermally conductive filler or a conductive filler. For example, the first resin-based material may include a pure epoxy resin or a pure polyimide resin. The first filling layer F_1 may have a capillary underfill (CUF) structure, but the present disclosure is not limited thereto. The first filling layer F_1 may limit and/or suppress a warpage phenomenon of the semiconductor package 10. For example, the first filling layer F_1 may disperse stress generated in the manufacturing process of the semiconductor package 10 by reinforcing mechanical bonding between the first bonding member 270 and the peripheral components thereof. Accordingly, the mechanical stability of the semiconductor package 10 may be improved and the warpage phenomenon may be limited and/or prevented. In some example embodiments, the first filling layer F_1 and the second filling layer F_2 may include the same material.

The second filling layer F_2 may be disposed between the second redistribution structure 150 and the heat dissipation member 162. The second filling layer F_2 may fill the second lower space US_2 formed between the plurality of second bonding members 161. The second filling layer F_2 may cover the plurality of second bonding members 161. The second filling layer F_2 may include at least one of a first resin-based material or a heat transfer material having a higher thermal conductivity than the first resin-based material. Here, the heat transfer material may include a second resin-based material including a different material from the first resin-based material. Additionally, the heat transfer material may include a non-resin-based material. Here, the second resin-based material may refer to a resin-based material to which impurities such as a heat conductive filler are added, unlike the first resin-based material. For example, the second resin-based material may include a resin-based binder and a heat conductive filler dispersed in the resin-based binder. The heat conductive filler may include at least one of alumina (Al₂O₃), boron nitride (BN), aluminum nitride (AlN), silica (SiO₂), metal powder particles, graphene, or graphite. The non-resin-based material may include at least one of heat conductive grease, graphite, indium-based solder, or a phase change material.

The second filling layer F_2 may have a capillary underfill (CUF) structure, but the present disclosure is not limited thereto. The second filling layer F_2 may suppress the warpage phenomenon of the semiconductor package 10. For example, the second filling layer F_2 may disperse stress generated in the manufacturing process of the semiconductor package 10 by reinforcing mechanical bonding between the second bonding member 161 and the peripheral components thereof. Accordingly, the mechanical stability of the semiconductor package 10 may be improved, and the warpage phenomenon may be limited and/or prevented. In some example embodiments, the second filling layer F_2 may additionally secure a heat transfer path, thereby rapidly transferring heat generated by the first semiconductor package 100 to the heat dissipation member 162. Accordingly, the reliability of the semiconductor package 10 may be improved. In some example embodiments, the first filling layer F_1 and the second filling layer F_2 may include the same material. In some example embodiments, the first filling layer F_1 and the second filling layer F_2 may include different materials. That is, the first filling layer F_1 and the second filling layer F_2 may be composed of different materials.

The gap filling layer GF may be disposed between the second semiconductor package 200 and the heat dissipation structure 160. For example, the gap filling layer GF may be disposed between the second semiconductor chip structure 220 and the heat dissipation member 162. For example, the gap filling layer GF may be disposed between the second encapsulant 240 and the heat dissipation member 162. The gap filling layer GF may extend in a third direction (e.g., Y-direction). In some example embodiments, a gap region G may be formed between the second semiconductor package 200 and the heat dissipation structure 160. For example, the gap region G may be formed between the second semiconductor package 200 and the heat dissipation member 162. The gap filling layer GF may fill the gap region G. The gap filling layer GF may be in contact with the upper surface of the second redistribution structure 150. The gap filling layer GF may be in contact with the first filling layer F_1 and/or the second filling layer F_2.

The gap filling layer GF may be in contact with the first side surface SA_1 of the heat dissipation structure 160. For example, the gap filling layer GF may be in contact with the first side surface SA_1 of the heat dissipation member 162. The gap filling layer GF may be in contact with the first side surface SB_1 of the second semiconductor package 200. For example, the gap filling layer GF may be in contact with the first side surface SB_1 of the second encapsulant 240. In some example embodiments, a height H_1 of the gap filling layer GF in the second direction (e.g., Z-direction) may be less than a height H_2 in the second direction (e.g., Z-direction) from an upper surface of the second semiconductor package 200 to the upper surface of the second redistribution structure 150. In some example embodiments, the height H_1 of the gap filling layer GF in the second direction (e.g., Z-direction) may be less than a length H_3 in the second direction (e.g., Z-direction) from an upper surface of the heat dissipation member 162 to the upper surface of the second redistribution structure 150.

In some example embodiments, as illustrated in the enlarged portion (‘E’) of an upper surface GF_US of the gap filling layer GF, the upper surface GF_US of the gap filling layer GF may have a concave shape. For example, the upper surface GF_US of the gap filling layer GF may have a concave curved surface. Here, a height H_4 in the second direction (e.g., Z-direction) from an upper surface of the second semiconductor package 200 to a point located at the lowest level of the upper surfaces GF_US of the gap filling layer GF, may be less than the height H_2 in the second direction (e.g., Z-direction) from the upper surface of the second semiconductor package 200 to the upper surface of the second redistribution structure 150. For example, the height H_2 in the second direction (e.g., Z-direction) from the upper surface of the second semiconductor package 200 to the upper surface of the second redistribution structure 150 may be 6 to 8 times higher than the height H_4 in the second direction (e.g., Z-direction) from the upper surface of the second semiconductor package 200 to the point located at the lowermost level of the upper surfaces GF_US of the gap filling layer GF. In some example embodiments, the upper surface GF_US of the gap filling layer GF may have a flat shape. For example, the upper surface GF_US of the gap filling layer GF may be coplanar with the upper surface of the second semiconductor package 200 or an upper surface of the heat dissipation structure 160.

In some example embodiments, the gap filling layer GF may include silicone-based adhesive materials. For example, the silicone-based adhesive material may include at least one of acetoxy-based silicone, alkoxy-based silicone, oxime-based silicone, amino-based silicone, silicone resin, silicone rubber, silylated polymer (SMP), or polydimethylsiloxane (PDMS). For example, the silicone-based adhesive material may include at least one of LOCTITE™ SI 5970 (Henkel), DOWSIL™ SE 4486 CV (Dow), DOWSIL™ TC-4525 (Dow), or SILCOOL™ TIA0220 (Momentive). In some example embodiments, the gap filling layer GF may be cured at room temperature or at low temperature by including the silicone-based adhesive material. Accordingly, the remaining components of the semiconductor package 10 may be limited and/or prevented from being damaged by the high temperature. In some example embodiments, the warpage phenomenon of the semiconductor package 10 may be suppressed by the gap filling layer GF. For example, the gap filling layer GF may strongly adhere the second semiconductor package 200 and the heat dissipation structure 160 mounted on the first semiconductor package 100. Accordingly, the gap filling layer GF may disperse the stress generated in the manufacturing process of the semiconductor package 10 by reinforcing the mechanical bonding of the second semiconductor package 200 and the heat dissipation structure 160. In some example embodiments, when the gap filling layer GF includes a flexible material, the gap filling layer GF may absorb the mechanical deformation of the semiconductor package 10. Accordingly, the mechanical stability of the semiconductor package 10 may be improved, and the warpage phenomenon may be limited and/or prevented. Additionally, the electrical reliability and stability of the semiconductor package 10 may be improved. In some example embodiments, the first filling layer F_1 and the gap filling layer GF may include different materials. The second filling layer F_2 and the gap filling layer GF may include different materials. Each of the first filling layer F_1, the second filling layer F_2, and the gap filling layer GF may include different materials. However, the present disclosure is not limited thereto, and the first filling layer F_1, the second filling layer F_2, and the gap filling layer GF may include the same material. For example, the gap filling layer GF may be formed integrally with the second filling layer F_2. Additionally, the gap filling layer GF may be formed integrally with the first filling layer F_1 and the second filling layer F_2.

In some example embodiments, the second bonding member 161 disposed below the heat dissipation member 162 may be referred to as the first bonding material layer. Additionally, the second filling layer F_2 disposed below the heat dissipation member 162 may be referred to as the second bonding material layer. That is, the first bonding material layer may correspond to the second bonding member 161, and the second bonding material layer may correspond to the second filling layer F_2, and vice versa. In some example embodiments, a region provided by the second redistribution layer 152 on the second redistribution structure 150 may be referred to as the first region. In some example embodiments, a region provided by the second insulating layer 151 on the second redistribution structure 150 may be referred to as the second region. The first and second bonding material layers may be bonded to the heat dissipation member 162 below the heat dissipation member 162. The first bonding material layer may extend from a first region of the second redistribution structure 150 and may thus be in contact with a lower surface of the heat dissipation member 162. The second bonding material layer may extend from the second region of the second redistribution structure 150 and may thus be in contact with the lower surface of the heat dissipation member. Here, the first bonding material layer and the second bonding material layer may be in contact with each other in a horizontal direction (e.g., X-direction or Y-direction). That is, the first bonding material layer and the second bonding material layer may be in contact with each other in the first direction (e.g., X-direction) or the third direction (e.g., Y-direction). The first bonding material layer and the second bonding material layer may overlap each other in the first direction (e.g., X-direction). In some example embodiments, the first bonding material layer and the second bonding material layer may include different materials. An elastic coefficient of the first bonding material layer and an elastic coefficient of the second bonding material layer may be different. For example, the elastic coefficient of the first bonding material layer may be greater than the elastic coefficient of the second bonding material layer. For example, a thermal conductivity of the first bonding material layer may be greater than a thermal conductivity of the second bonding material layer. In some example embodiments, the gap filling layer GF may be formed integrally with the second bonding material layer. In some example embodiments, a plurality of first bonding material layers may be spaced apart from each other in a first direction (e.g., X-direction), and the second bonding material layer may fill a lower space formed between the plurality of first bonding material layers. Here, the lower space may correspond to the second lower space US_2.

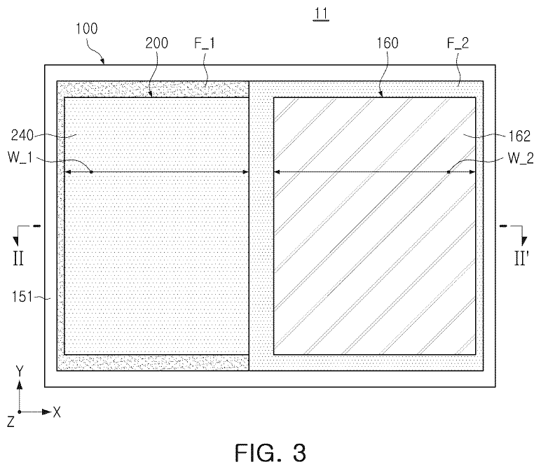

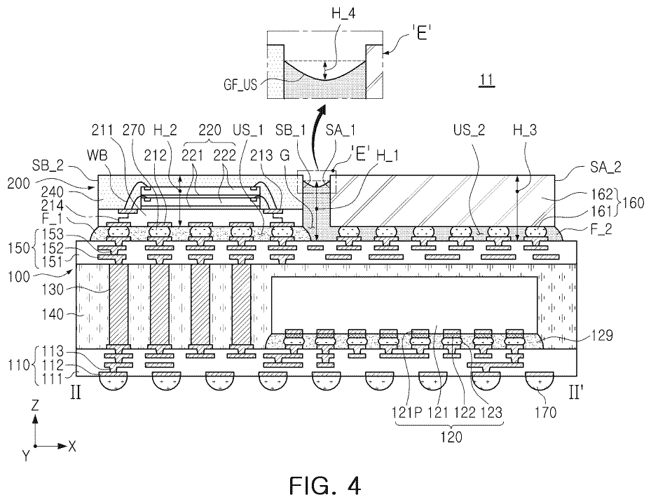

FIG. 3 is a plan view illustrating a semiconductor package according to some example embodiments of the present disclosure. FIG. 4 is a cross-sectional view taken along line II-II′ of FIG. 3. For convenience of explanation, detailed descriptions of components identical or similar to those described in detail in the example embodiment described in FIGS. 1 and 2 may be omitted. Referring to FIGS. 3 and 4, a semiconductor package 11 according to some example embodiments of the present disclosure may include a first semiconductor package 100, a second semiconductor package 200, and a heat dissipation structure 160. The semiconductor package 11 may include a first filling layer F_1 and a second filling layer F_2. For example, the semiconductor package 11 may include the first filling layer F_1 filling the first lower space US_1 formed between the second semiconductor structure 220 and the second redistribution structure 150 or between the plurality of first bonding members 161. For example, the semiconductor package 11 may include the second filling layer F_2 filling the gap region G formed between the second semiconductor package 200 and the heat dissipation member 162 and the second lower space US_2 formed between the heat dissipation member 162 and the second redistribution structure 150. In this case, an upper surface GF_US of the second filling layer F_2 filling the gap region G may have a concave shape. For example, the upper surface GF_US of the second filling layer F_2 filling the gap region G may have a concave curved surface. Here, the height H_4 in the second direction (e.g., Z-direction) from the upper surface of the second semiconductor package 200 to the point disposed on a lowermost level, among the upper surfaces GF_US of the second filling layer F_2 filling the gap region G may be less than the height H_2 in the second direction (e.g., Z-direction) from the upper surface of the second semiconductor package 200 to the upper surface of the second redistribution structure 150. Specifically, the height H_2 in the second direction (e.g., Z-direction) from the upper surface of the second semiconductor package 200 to the upper surface of the second redistribution structure 150 may be 6 to 8 times higher than the height H_4 in the second direction (e.g., Z-direction) from the upper surface of the second semiconductor package 200 to the point located at the lowermost level of the upper surfaces GF_US of the second filling layer F_2 filling the gap region G. In some example embodiments, the upper surface GF_US of the second filling layer F_2 filling the gap region G may have a flat shape. For example, the upper surface GF_US of the second filling layer F_2 filling the gap region G may be coplanar with the upper surface of the second semiconductor package 200 or the upper surface of the heat dissipation structure 160.

In some example embodiments, the first filling layer F_1 and the second filling layer F_2 may be in contact with each other. The first filling layer F_1 may include a first resin-based material. The second filling layer F_2 may include at least one of the first resin-based material or a thermal interface material (TIM). The thermal interface material may include at least one of the second resin-based material or a non-resin-based material.

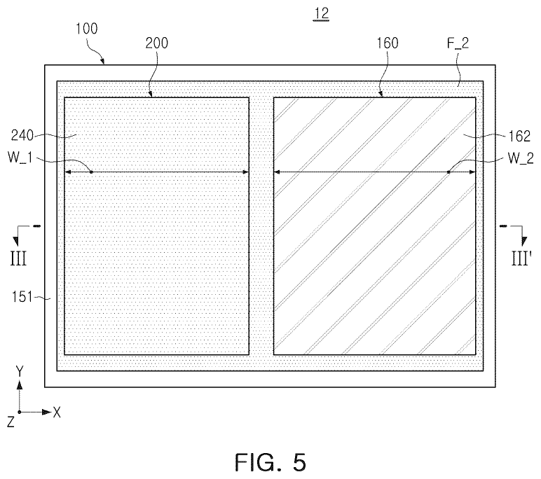

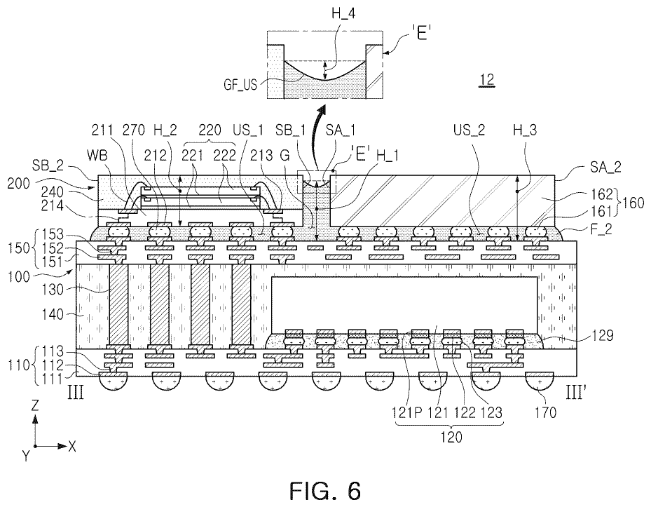

FIG. 5 is a plan view illustrating a semiconductor package according to some example embodiments of the present disclosure. FIG. 6 is a cross-sectional view taken along line III-III′ of FIG. 5. For convenience of explanation, detailed descriptions of components identical or similar to those described in detail in the example embodiment described in FIGS. 1 to 4 may be omitted. Referring to FIGS. 5 and 6, a semiconductor package 12 according to some example embodiments of the present disclosure may include a first semiconductor package 100, a second semiconductor package 200, and a heat dissipation structure 160. The semiconductor package 12 may include a second filling layer F_2. Here, the second filling layer F_2 may fill the first lower space US_1 formed between the second semiconductor structure 220 and the second redistribution structure 150 (also referred to as second wiring structure), the gap region G formed between the second semiconductor package 200 and the heat dissipation member 162, and the second lower space US_2 formed between the heat dissipation member 162 and the second redistribution structure 150. For example, the semiconductor package 12 may include the first lower space US_1 formed between the plurality of first bonding members 161, the second lower space US_2 formed between the plurality of second bonding members 270, and the second filling layer F_2 filling the gap region G formed between the second semiconductor package 200 and the heat dissipation member 162. In this case, the upper surface GF_US of the second filling layer F_2 filling the gap region G may have a concave shape. For example, the upper surface GF_US of the second filling layer F_2 filling the gap region G may have a concave curved surface. Here, the height H_4 in the second direction (e.g., Z-direction) from the upper surface of the second semiconductor package 200 to the point disposed on the lowermost level, among the upper surfaces GF_US of the second filling layer F_2 filling the gap region G may be less than the height H_2 in the second direction (e.g., Z-direction) from the upper surface of the second semiconductor package 200 to the upper surface of the second redistribution structure 150. Specifically, the height H_2 in the second direction (e.g., Z-direction) from the upper surface of the second semiconductor package 200 to the upper surface of the second redistribution structure 150 may be 6 to 8 times higher than the height H_4 in the second direction (e.g., Z-direction) from the upper surface of the second semiconductor package 200 to the point disposed on the lowermost level, among the upper surfaces GF_US of the second filling layer F_2 filling the gap region G. In some example embodiments, the upper surface GF_US of the second filling layer F_2 filling the gap region G may have a flat shape. For example, the upper surface GF_US of the second filling layer F_2 filling the gap region G may be coplanar with the upper surface of the second semiconductor package 200 or the upper surface of the heat dissipation structure 160. The second filling layer F_2 may include at least one of the first resin-based material or thermal interface materials (TIM). The thermal interface materials may include at least one of the second resin-based material or non-resin-based material.

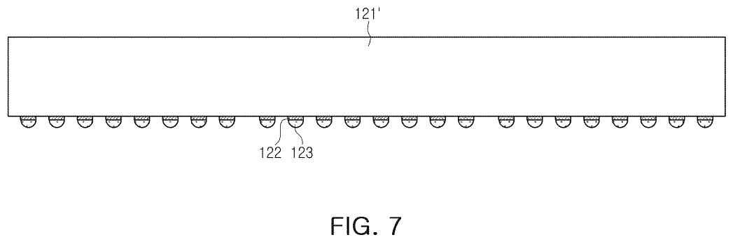

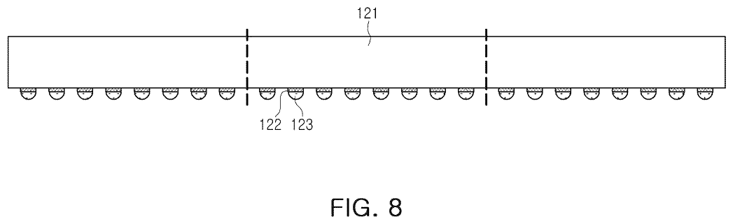

FIGS. 7 to 26 are intermediate operation views illustrating a method of manufacturing a semiconductor package according to some example embodiments of the present disclosure. In the following FIGS. 7 to 26, for convenience of explanation, detailed descriptions of components identical or similar to those described in detail in the embodiments described in FIGS. 1 to 6 may be omitted. FIGS. 7 and 8 are views illustrating a process sequence illustrating a method of manufacturing a first semiconductor chip structure 120 according to the example embodiment described in FIGS. 1 to 6. Referring to FIG. 7, a connection pillar 122 and a connection solder 123 may be formed on a lower surface of a preliminary semiconductor chip 121′. In forming the connection pillar 122 and the connection solder 123, a plurality of connection pillars 122 may be formed spaced apart from each other on the lower surface of the preliminary semiconductor chip 121′ and a plurality connection solders 123 may be formed on the plurality connection pillars 122. The preliminary semiconductor chip 121′ may include a semiconductor wafer and a semiconductor wafer integrated circuit (IC) comprised of a semiconductor element such as silicon or germanium, or a compound semiconductor such as silicon carbide (SiC), gallium arsenide (GaAs), indium arsenide (InAs) and indium phosphide (InP). The preliminary semiconductor chip 121′ may be a bare semiconductor chip in which a separate bump or a separate interconnection layer is formed, but the present disclosure is not limited thereto. Referring to FIG. 8, an upper surface of the preliminary semiconductor chip 121′ may be etched to form a first semiconductor chip 121. An etching process may include a grinding process, an etch back process, and/or a Chemical Mechanical Polishing (CMP) process. The first semiconductor chip 121 may be formed to have a desired thickness by the etching process.

Next, a cut process may be performed, to form individual first semiconductor chips 121. The cut process may be performed by a blade dicing process, a laser dicing process, or the like. Referring to FIGS. 1 to 6 together, the cut first semiconductor chip 121 may form the first semiconductor chip structure 120 mounted on the first redistribution structure 110.

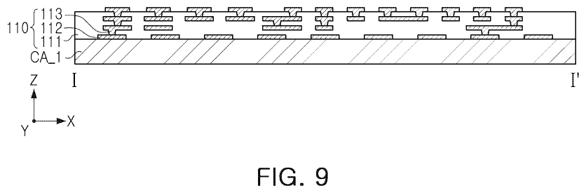

FIGS. 9 to 20 are views illustrating a method of manufacturing a semiconductor package 10 according to the example embodiment described in FIGS. 1 and 2 according to the process sequence. Referring to FIG. 9, a first redistribution structure 110 may be formed on a first carrier CA_1. For example, in first carrier CA_1, a polymer layer including a curable resin and a metal layer including nickel (Ni) and titanium (Ti) may be sequentially coated on a copper clad laminate (CCL). The first redistribution structure 110 may include a first insulating layer 111, a plurality of first redistribution layers 112, and a plurality of first redistribution vias 113. The first insulating layer 111 may be formed by sequentially applying and curing a photosensitive material, for example, PID. The plurality of first redistribution layers 112 and the plurality of first redistribution vias 113 may be formed by performing an exposure process and a development process to form via holes penetrating through the first insulating layer 111, and patterning a metallic material on the first insulating layer 111 using a plating process. The plurality of first redistribution layers 112 may also be formed on the upper surface of the first redistribution structure 110, and a barrier layer including nickel (Ni), gold (Au), or the like may be further formed.

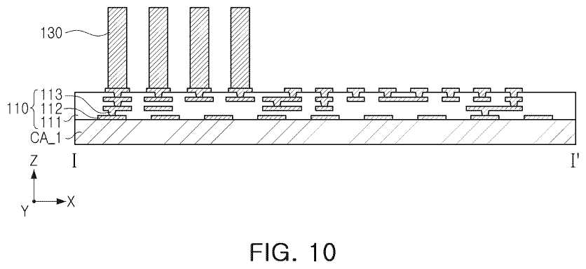

Referring to FIG. 10, a plurality of interconnect structures 130 may be formed on a plurality of first redistribution layers 112 formed on the first insulating layer 111. The interconnect structures 130 may be formed by performing a plating process and a patterning process. The interconnect structures 130 may include a metallic material such as copper (Cu). According to an example embodiment, a metal seed layer including titanium (Ti) and copper (Cu) may be formed on a lower surface of the interconnect structure 130.

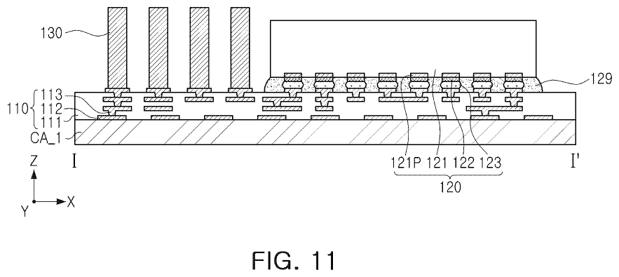

Referring to FIG. 11, the first semiconductor chip structure 120 may be mounted on the first redistribution structure 110. The first semiconductor chip structure 120 may be a first semiconductor chip structure 120 formed by a manufacturing process described with reference to FIGS. 7 and 8, and may include a first semiconductor chip 121. The first semiconductor chip structure 120 may be mounted in a flip-chip manner. For example, the first semiconductor chip structure 120 may be connected to the plurality of first redistribution layers 112 through a connection pillar 122 and a connection solder 123 formed on a connection terminal 121P. An underfill layer 129 may be formed between the first semiconductor chip structure 120 and the first redistribution structure 110. The underfill layer 129 may be formed using a CUF process, but the present disclosure is not limited thereto.

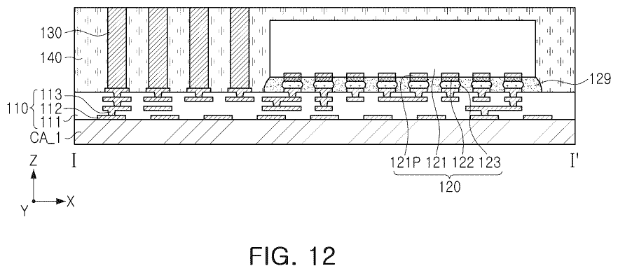

Referring to FIG. 12, a first encapsulant 140 may be formed to encapsulate at least a portion of each of the first semiconductor chip structure 120 and the interconnect structure 130. The upper surface of the first encapsulant 140 may be formed on a higher level than an upper surface of the interconnect structure 130. The first encapsulant 140 may be formed by, for example, applying and curing EMC. Then, a planarization process may be applied to an upper portion of the first encapsulant 140. The planarization process may include a grinding process and a Chemical Mechanical Polishing (CMP) process. A portion of the interconnect structure 130 and the first encapsulant 140 may be etched by the planarization process, and an upper end of the interconnect structure 130 may be exposed through the upper surface of the first encapsulant 140. Accordingly, a flat surface formed by the upper surface of the interconnect structure 130 and the upper surface of the first encapsulant 140 may be formed.

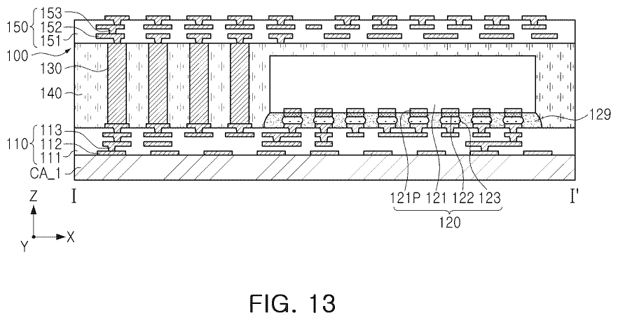

Referring to FIG. 13, a second redistribution structure 150 covering the upper surface of the first encapsulant 140 and the upper surface of the interconnect structure 130 may be formed. The second redistribution structure 150 may be formed by a process similar to that of the first redistribution structure 110. The second insulating layer 151 may be formed by sequentially applying and curing a photosensitive material, for example, PID. A plurality of second redistribution layers 152 and a plurality of second redistribution vias 153 may be formed by performing an exposure process and a development process to form a via hole penetrating through the upper insulating layer 151, and patterning a metallic material on the upper insulating layer 151 using a plating process. A barrier layer may be formed on a pad portion exposed on the upper surface of the second redistribution structure 150.

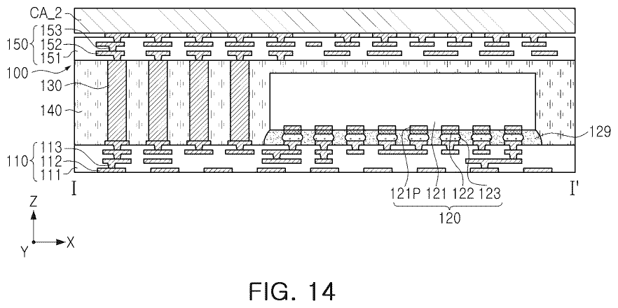

Referring to FIG. 14, a second carrier CA_2 may be formed on the second redistribution structure 150, and a package may be turned over to perform a subsequent process. The first carrier CA_1 may be removed to expose the upper surface of the first redistribution structure 110, and one surface of the plurality of first redistribution layers 112 disposed in an uppermost portion may be exposed.

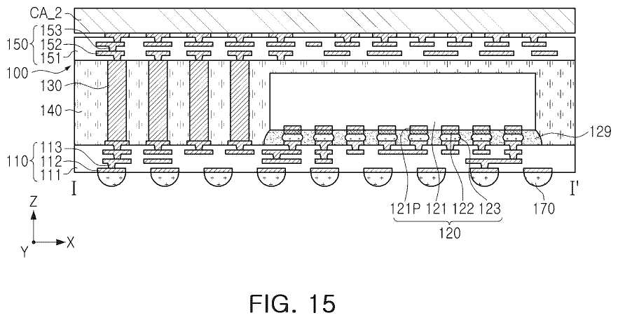

Referring to FIG. 15, a plurality of external connection bumps 170 may be formed to contact the plurality of exposed first redistribution layers 112.

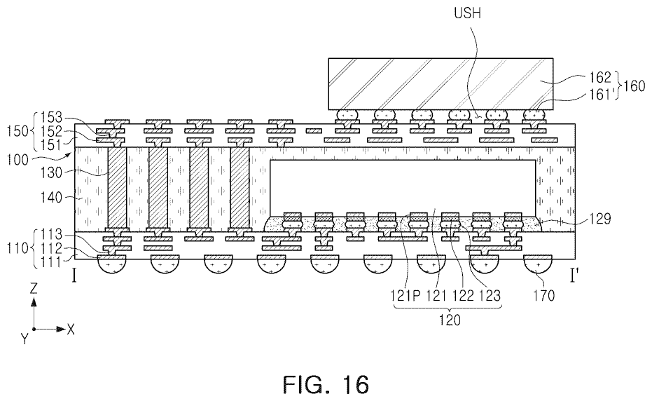

Referring to FIG. 16, the package may be turned over again to proceed with the subsequent process. In this case, the second carrier CA_2 may be removed. A heat dissipation structure 160 may be mounted on a plurality of second redistribution layers 152 disposed on the second insulating layer 151. The heat dissipation structure 160 may include a plurality of heat dissipation bonding members 161′ and a heat dissipation member 162. In some example embodiments, the heat dissipation bonding member 161′ may bond the heat dissipation member 162 and the second redistribution structure 150. The heat dissipation bonding member 161′ may correspond to the second bonding member 161 according to the example embodiment described in FIGS. 1 to 6. A plurality of heat dissipation bonding members 161′ may be mounted on a plurality of second redistribution layers 152, and the heat dissipation member 162 may be mounted on a plurality of heat dissipation bonding members 161'. The plurality of heat dissipation bonding members 161′ may be spaced apart from each other in the first direction (e.g., X-direction). Accordingly, a lower heat dissipation space USH may be formed between the plurality of heat dissipation bonding members 161′. The lower heat dissipation space USH may correspond to the second lower space US_2 according to the example embodiment described in FIGS. 1 to 6. Here, the plurality of second redistribution layers 152 disposed below the heat dissipation structure 160 may not be electrically connected to the remaining components of the semiconductor package. Accordingly, the heat dissipation structure 160 may not be electrically connected to the remaining components of the semiconductor package.

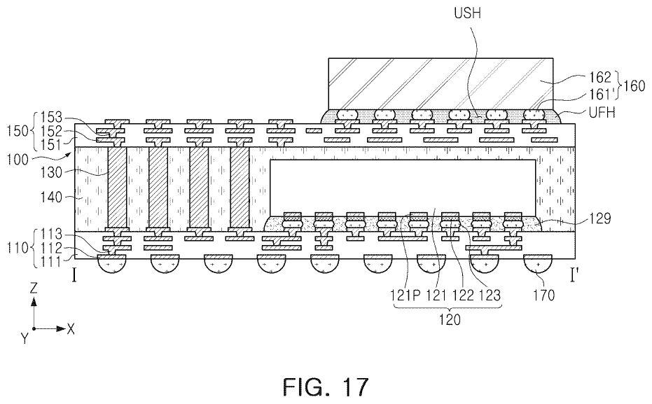

Referring to FIG. 17, a lower heat dissipation filling layer UFH may be formed between the second redistribution structure 150 and the heat dissipation member 162. Here, the lower heat dissipation filling layer UFH may correspond to the second filling layer F_2 according to the example embodiment disclosed in FIGS. 1 to 6. The lower heat dissipation filling layer UFH may fill the lower heat dissipation space USH. That is, the lower heat dissipation filling layer UFH may cover a plurality of heat dissipation bonding members 161′. The lower heat dissipation filling layer UFH may be formed by a capillary underfill (CUF) method, or the like.

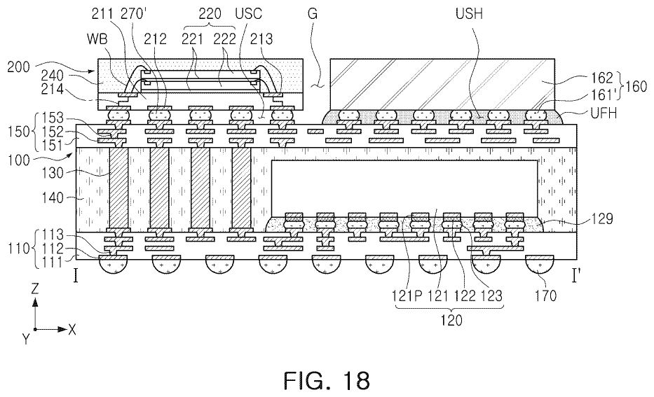

Referring to FIG. 18, the second semiconductor package 200 spaced apart from the heat dissipation structure 160 in the horizontal direction may be mounted on the second redistribution structure 150. Accordingly, a gap region G may be formed between the second semiconductor package 200 and the heat dissipation structure 160. The second semiconductor package 200 may include a redistribution substrate 211, a second semiconductor chip structure 220, a second encapsulant 240, and a plurality of second bonding members 270. For example, the redistribution substrate 211 may be mounted on the second redistribution structure 150. For example, the second semiconductor chip structure 220 may be mounted on the second redistribution structure 150. For example, the second semiconductor chip structure 220 may be mounted on the redistribution substrate 211. In some example embodiments, the second encapsulant 240 may be formed before the second semiconductor package 200 is mounted on the second redistribution structure 150. Here, the second encapsulant 240 may cover the second semiconductor chip structure 220. For example, the second encapsulant 240 may be formed by applying and curing an epoxy molding compound (EMC). A plurality of chip bonding members 270′ may be formed below the redistribution substrate 211. Here, the chip bonding members 270′ may bond the second semiconductor package 200 including the second semiconductor chip structure 220 and the second redistribution structure 150. The chip bonding members 270′ may correspond to the first bonding members 270 according to the example embodiment described in FIGS. 1 to 6. The plurality of chip bonding members 270′ may be spaced apart from each other in the first direction (e.g., X-direction). Accordingly, a chip sub space USC may be formed between the plurality of chip bonding members 270′. The second semiconductor package 200 may be electrically connected to the plurality of second redistribution layers 152 through the chip bonding members 270′.

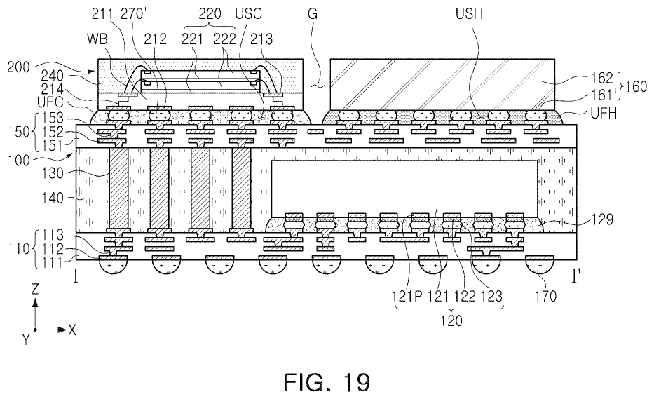

Referring to FIG. 19, a lower chip filling layer UFC may be formed between the second redistribution structure 150 and the second semiconductor chip structure 220. The lower chip filling layer UFC may be formed between the second redistribution structure 150 and the redistribution substrate 211. The lower chip filling layer UFC may correspond to the first filling layer F_1 according to the example embodiment described in FIGS. 1 to 6. The lower chip filling layer UFC may fill the lower chip space USC. That is, the lower chip filling layer UFC may cover the plurality of chip bonding members 270′. The lower chip filling layer UFC may be formed by a capillary underfill (CUF) method, or the like.

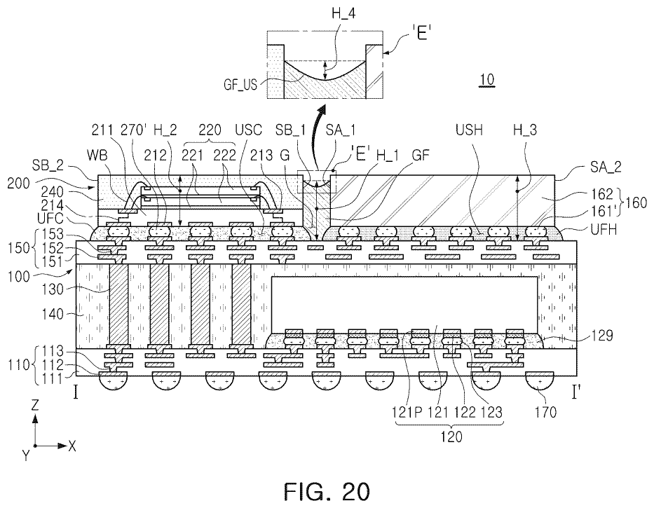

Referring to FIG. 20, a gap filling layer GF may be formed between the heat dissipation member 162 and the second encapsulant 240. Alternatively, the gap filling layer GF may be formed between the heat dissipation structure 160 and the second semiconductor package 200. The gap filling layer GF may fill the gap region G. The gap filling layer GF may be formed by a gap fill method or a capillary underfill method. Each of the lower heat dissipation filling layer UFH, the lower chip filling layer UFC, and the gap filling layer GF may include different materials. For example, the lower heat dissipation filling layer UFH may include at least one of a first resin-based material or a heat transfer material. The lower chip filling layer UFC may include the first resin-based material. The gap filling layer GF may include a silicon-based adhesive material. The warpage phenomenon of the semiconductor package 10 may be suppressed by the lower heat dissipation filling layer UFH, the lower chip filling layer UFC and the gap filling layer GF. For example, the lower heat dissipation filling layer UFH, the lower chip filling layer UFC and the gap filling layer GF may disperse the stress generated in the manufacturing process of the semiconductor package 10 by reinforcing the mechanical bonding between the first bonding member 161 and the peripheral components thereof. Accordingly, the mechanical stability of the semiconductor package 10 may be improved, and the warpage phenomenon may be limited and/or prevented.

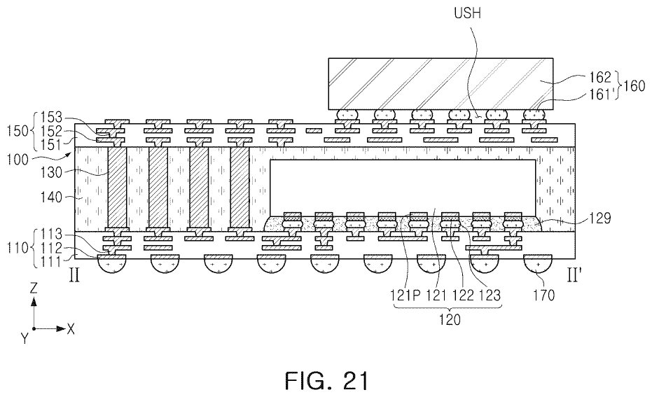

FIGS. 21 to 23 are intermediate operation views illustrating a manufacturing method of the semiconductor package 11 according to the example embodiment described in FIGS. 3 and 4. Referring to FIG. 21, a heat dissipation structure 160 may be mounted on a plurality of second redistribution layers 152 disposed on a second insulating layer 151. The operation illustrated in FIG. 21 may be a result according to the operation illustrated in FIGS. 9 to 16. Accordingly, the components of FIG. 21 may be identical or similar to the components of FIG. 16.

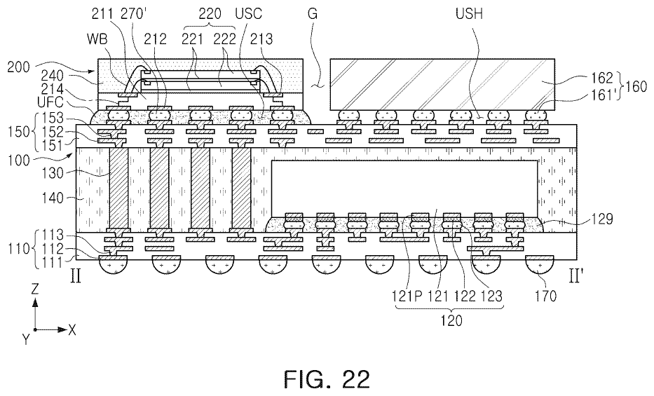

Referring to FIG. 22, a second semiconductor package 200 spaced apart from a heat dissipation structure 160 in a horizontal direction may be mounted on a second redistribution structure 150. Accordingly, a gap region G may be formed between the second semiconductor package 200 and the heat dissipation structure 160. The second semiconductor package 200 may include a redistribution substrate 211, a second semiconductor chip structure 220, a second encapsulant 240 and a plurality of chip bonding members 270'. For example, the redistribution substrate 211 may be mounted on the second redistribution structure 150. For example, the second semiconductor chip structure 220 may be mounted on the second redistribution structure 150. For example, the second semiconductor chip structure 220 may be mounted on the redistribution substrate 211. In some example embodiments, the second encapsulant 240 may be formed before the second semiconductor package 200 is mounted on the second redistribution structure 150. Here, the second encapsulant 240 may cover the second semiconductor chip structure 220. For example, the second encapsulant 240 may be formed by applying and curing EMC. A plurality of chip bonding members 270′ may be formed below the redistribution substrate 211. The plurality of chip bonding members 270′ may be spaced apart from each other in the horizontal direction. Accordingly, a chip sub space USC may be formed between the plurality of chip bonding members 270′. The second semiconductor package 200 may be electrically connected to a plurality of second redistribution layers 152 through the plurality of chip bonding members 270′. Then, unlike as illustrated in FIGS. 9 to 20, a lower chip filling layer UFC may be first formed between the second redistribution structure 150 and the second semiconductor chip structure 220. Alternatively, a lower chip filling layer UFC may be formed between the second redistribution structure 150 and the redistribution substrate 211. The lower chip filling layer UFC can fill the lower chip space USC. That is, the lower chip filling layer UFC may cover the plurality of chip bonding members 270′. The lower chip filling layer UFC may be formed by a capillary underfill (CUF) method, or the like.

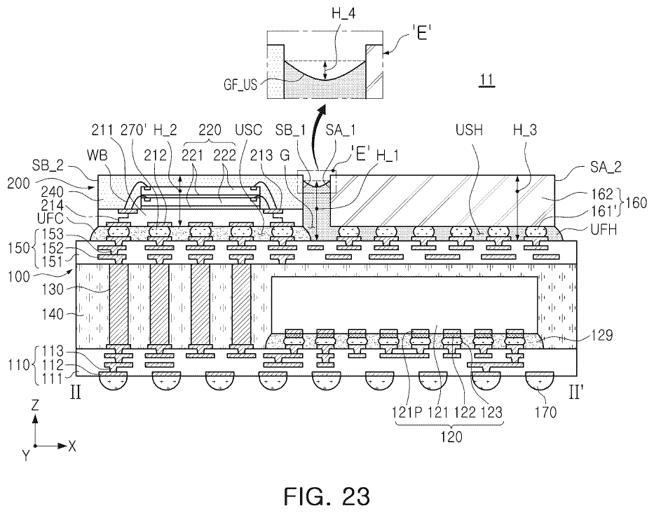

Referring to FIG. 23, a lower heat dissipation filling layer UFH may be formed to fill a lower heat dissipation space USH formed between the second redistribution structure 150 and a heat dissipation member 162 and a gap region G formed between the heat dissipation member 162 and the second encapsulant 240. The lower heat dissipation filling layer UFH may be formed by a capillary underfill method, or the like. Unlike those illustrated in FIGS. 21 to 23, the lower heat dissipation filling layer UFH may be formed first, and then the lower chip filling layer UFC may be formed to fill the lower chip space USC and the gap region G. The warpage phenomenon of the semiconductor package 11 may be suppressed by the lower heat dissipation filling layer UFH and the lower chip filling layer UFC. For example, the lower heat dissipation filling layer UFH may disperse stress generated in the manufacturing process of the semiconductor package 11 by reinforcing the mechanical bonding between the heat dissipation bonding member 161 and the peripheral components thereof. Accordingly, the mechanical stability of the semiconductor package 11 may be improved and the warping phenomenon may be limited and/or prevented.

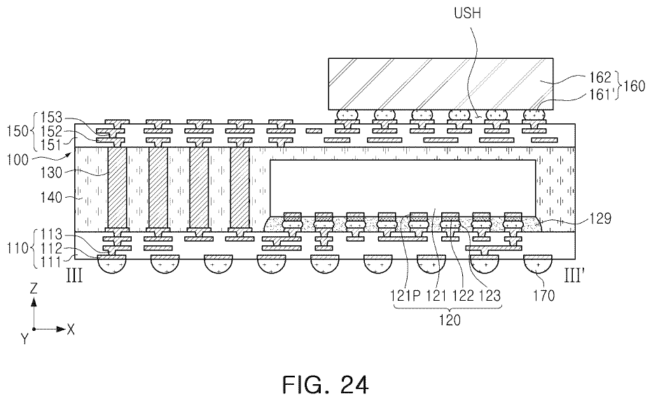

FIGS. 24 to 26 are intermediate operation views illustrating a method of manufacturing the semiconductor package 12 according to the example embodiment described in FIGS. 5 and 6. Referring to FIG. 24, a heat dissipation structure 160 may be mounted on a plurality of second redistribution layers 152 disposed on the second insulating layer 151. An operation illustrated in FIG. 24 may be a result according to the operation illustrated in FIGS. 9 to 16. Accordingly, the components of FIG. 24 may be identical or similar to the components of FIG. 16.

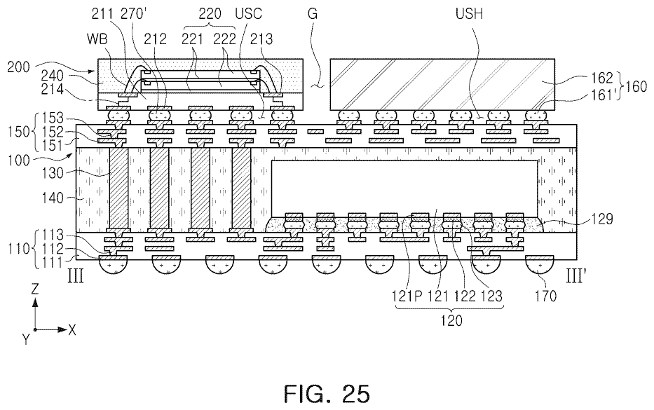

Referring to FIG. 25, a second semiconductor package 200 spaced apart from a heat dissipation structure 160 in the horizontal direction may be mounted on a second redistribution structure 150. Accordingly, a gap region G may be formed between the second semiconductor package 200 and the heat dissipation structure 160. The second semiconductor package 200 may include a redistribution substrate 211, a second semiconductor chip structure 220, a second encapsulant 240, and a plurality of second bonding members 270. For example, the redistribution substrate 211 may be mounted on the second redistribution structure 150. For example, the second semiconductor chip structure 220 may be mounted on the second redistribution structure 150. For example, the second semiconductor chip structure 220 may be mounted on the redistribution substrate 211. In some example embodiments, the second encapsulant 240 may be formed before the second semiconductor package 200 is mounted on the second redistribution structure 150. Here, the second encapsulant 240 may cover the second semiconductor chip structure 220. For example, the second encapsulant 240 may be formed by applying and curing EMC. A plurality of chip bonding members 270′ may be formed below the redistribution substrate 211. The plurality of chip bonding members 270′ may be spaced apart from each other in the first direction (e.g., X-direction). Accordingly, a chip sub space USC may be formed between the plurality of chip bonding members 270′. The second semiconductor package 200 may be electrically connected to a plurality of second redistribution layers 152 through the plurality of chip bonding members 270′.

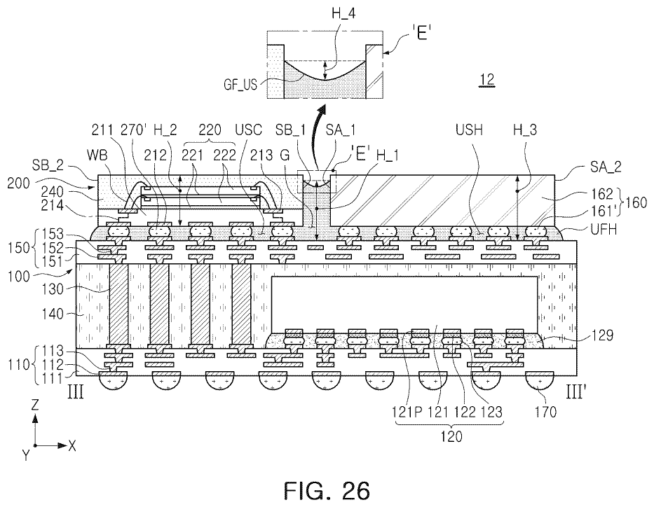

Referring to FIG. 26, a lower heat dissipation filling layer UFH may be formed to fill a lower heat dissipation space USH formed between a second redistribution structure 150 and a heat dissipation member 162, a gap region G formed between a heat dissipation member 162 and a second encapsulant 240, and a lower chip space USC formed between a second redistribution structure 150 and a second semiconductor chip structure 220. The lower heat dissipation filling layer UFH may be formed by a capillary underfill method, or the like. The warpage phenomenon of the semiconductor package 12 may be suppressed by the lower heat dissipation filling layer UFH. For example, the lower heat dissipation filling layer UFH may disperse stress generated in the manufacturing process of the semiconductor package 12 by reinforcing the mechanical bonding between the first bonding member 161 and the peripheral components thereof. Accordingly, the mechanical stability of the semiconductor package 12 may be improved, and the warpage phenomenon may be limited and/or prevented.

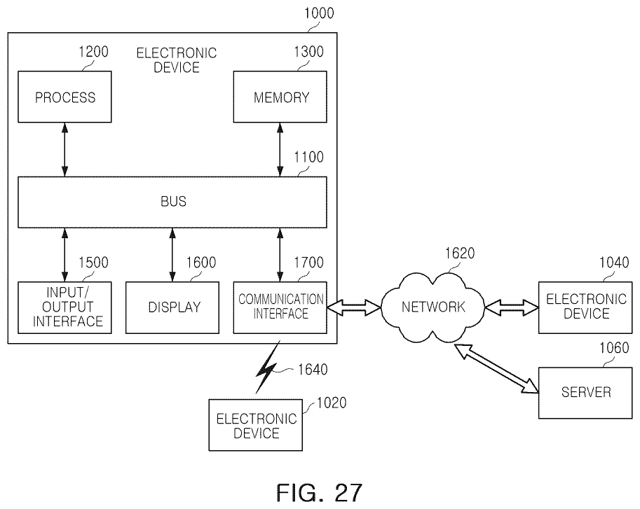

FIG. 27 is a block diagram schematically illustrating an electronic device including a semiconductor package according to some example embodiments of the present disclosure. Referring to FIG. 27, an electronic device 1000 may include a bus 1100, a processor 1200, a memory 1300, an input/output interface 1500, a display 1600, and a communication interface 1700. In some example embodiments, the electronic device 1000 may omit at least one of the components or additionally include other components. The bus 1100 may include circuit connecting components for connecting components (e.g., the processor 1200, memory 1300, input/output interface 1500, display 1600, and communication interface 1700) to each other and for transmitting communication (e.g., control messages or data) between the components. The processor 1200 may include one or more of a central processing unit, an application processor, or a communication processor (CP). The processor 1200 may, for example, execute operations or data processing related to control and/or communication of at least one other component of the electronic device 1000.

The memory 1300 may include volatile and/or nonvolatile memory. The memory 1300 may store, for example, instructions or data related to at least one other component of the electronic device 1000. In some example embodiments, the memory 1300 may store software and/or programs. In some example embodiments, the electronic device 1000 may include at least one semiconductor package 10, 11 or 12 according to the example embodiment described in FIGS. 1 to 26. Here, the at least one semiconductor package 10, 11 or 12 may include components corresponding to the processor 1200 and/or the memory 1300, respectively. For example, the processor 1200 may correspond to the first semiconductor package 100 according to the example embodiment described in FIGS. 1 to 26. For example, the memory 1300 may correspond to the second semiconductor package 200 according to the example embodiment described in FIGS. 1 to 26.

The input/output interface 1500 may, for example, transmit a command or data input from a user or another external device to other component(s) of the electronic device 1000, or may output a command or data received from other component(s) of the electronic device 1000 to the user or other external device.

The display 1600 may, for example, include a liquid crystal display (LCD), a light emitting diode (LED) display, an organic light emitting diode (OLED) display, a micro electro mechanical system (MEMS) display, or an electronic paper display. The display 1600 may, for example, display various contents (e.g., text, images, videos, icons, and/or symbols, etc.) to the user. The display 1600 may include a touch screen and may receive, for example, touch, gesture, proximity, or hovering inputs using an electronic pen or a part of the user's body. The communication interface 1700 may establish communication between, for example, the electronic device 1000 and an external device (e.g., a first external electronic device 1020, a second external electronic device 1040, or a server 1060). For example, the communication interface 1700 may be connected to a network 1620 via wireless or wired communication to communicate with the external device (e.g., a second external electronic device 1040 or a server 1060).

The wireless communication may include, for example, cellular communication using at least one of LTE, LTE Advance (LTE-A), code division multiple access (CDMA), wideband CDMA (WCDMA), a universal mobile telecommunications system (UMTS), Wireless Broadband (WiBro), or Global System for Mobile Communications (GSM). In an example embodiment, the wireless communication may include, for example, at least one of wireless fidelity (Wi-Fi), Bluetooth, Bluetooth low energy (BLE), Zigbee, near field communication (NFC), Magnetic Secure Transmission, Radio Frequency (RF), or Body Area Network (BAN). In an example embodiment, the wireless communication may include GNSS. The GNSS may be, for example, Global Positioning System (GPS), Global Navigation Satellite System (Glonass), Beidou Navigation Satellite System (hereinafter referred to as “Beidou”) or Galileo, the European global satellite-based navigation system. Hereinafter, in this document, “GPS” may be used interchangeably with “GNSS.” The wired communication may include at least one of, for example, a universal serial bus (USB), a high definition multimedia interface (HDMI), a recommended standard232 (RS-232), a power line communication, or a plain old telephone service (POTS). The network 1620 may include a telecommunications network, for example, at least one of a computer network (e.g., a LAN or WAN), the Internet, or a telephone network.

Each of the first and second external electronic devices 1020 and 1040 may be the same or a different type of device as the electronic device 1000. According to various example embodiments, all or some of the operations executed in the electronic device 1000 may be executed in another or multiple electronic devices (e.g., the electronic device 1020 and 1040, or the server 1060). According to an example embodiment, when the electronic device 1000 is to perform a function or a service automatically or upon request, instead of executing the function or service by itself or additionally, the electronic device 1000 may request at least some functions associated therewith from another device (e.g., the electronic device 1020 and 1040, or the server 1060). The other electronic device (e.g., the electronic device 1020 and 1040, or the server 1060) may execute the requested function or additional function, and may transmit a result thereof to the electronic device 1000. The electronic device 1000 may process the received result unchangeably or additionally to provide the requested function or service. For this purpose, for example, cloud computing, distributed computing, or client-server computing technology may be used. The electronic devices 1000, 1020 and 1040 may be a mobile phone, a tablet, a laptop computer, a wearable device, or the like, but the present disclosure is not limited thereto.

According to some example embodiments of the present disclosure to address above-described technical aspects, a method of manufacturing a semiconductor package may include: forming a first redistribution structure; forming an interconnect structure on the first redistribution structure; mounting a first semiconductor chip structure on the first redistribution structure; forming a first encapsulant covering the interconnect structure and the first semiconductor chip structure; forming a second redistribution structure on the interconnect structure, the first semiconductor chip structure and the first encapsulant; mounting a heat dissipation member on the second redistribution structure; forming a lower heat dissipation filling layer between the second redistribution structure and the heat dissipation member; mounting a second semiconductor chip structure spaced apart from the heat dissipation member on the second redistribution structure in a first direction, forming a lower chip filling layer between the second redistribution structure and the second semiconductor chip structure; and forming a gap filling layer between the heat dissipation member and the second semiconductor chip structure.

According to some example embodiments of the present disclosure to address the above-described technical aspects, in the method of manufacturing a semiconductor package, a lower heat dissipation filling layer, a lower chip filling layer, and a gap filling layer may be formed so that each of the lower heat dissipation filling layer, the lower chip filling layer and the gap filling layer includes different materials.

According to some example embodiments of the present disclosure to address the above-described technical aspect, the mounting a heat dissipation member may further include forming a plurality of heat dissipation bonding members disposed below the heat dissipation member on the second redistribution structure and spaced apart from each other in the first direction, and the lower heat dissipation filling layer may cover the plurality of heat dissipation bonding members.

According to some example embodiments of the present disclosure to address the above-described technical aspects, the mounting a second semiconductor chip structure may further include forming a plurality of chip bonding members disposed below the second semiconductor chip structure on the second redistribution structure and spaced apart from each other in the first direction, and the lower chip filling layer may cover the plurality of chip bonding members.

According to some example embodiments of the present disclosure to address the above-described technical aspect, the forming a gap filling layer may further include forming the gap filling layer so that an upper surface of the gap filling layer has a concave curved surface.

According to some example embodiments of the present disclosure to address the above-described technical aspects, a method of manufacturing a semiconductor package may include: forming a first redistribution structure; forming an interconnect structure on the first redistribution structure; mounting a first semiconductor chip structure on the first redistribution structure; forming a first encapsulant covering the interconnect structure and the first semiconductor chip structure; forming a second redistribution structure on the interconnect structure, the first semiconductor chip structure and the first encapsulant; mounting a heat dissipation member on the second redistribution structure; mounting a second semiconductor chip structure spaced apart from the heat dissipation member on the second redistribution structure in a first direction; forming a lower chip filling layer to fill a lower chip space formed between the second redistribution structure and the second semiconductor chip structure; and forming a lower heat dissipation filling layer to fill a lower heat dissipation space formed between the second redistribution structure and the heat dissipation member and a gap region formed between the heat dissipation member and the second semiconductor chip structure.

According to some example embodiments of the present disclosure to address the above-described technical aspects, the mounting a heat dissipation member may further include forming a plurality of heat dissipation bonding members disposed below the heat dissipation member on the second redistribution structure and spaced apart from each other in the first direction, and the lower heat dissipation filling layer may cover the plurality of heat dissipation bonding members.

According to some example embodiments of the present disclosure to address the above-described technical aspects, the heat dissipation member may include silicon.

According to some example embodiments of the present disclosure to address the above-described technical aspects, the mounting a second semiconductor chip structure may further include forming a plurality of chip bonding members disposed below the second semiconductor chip structure on the second redistribution structure and spaced apart from each other in the first direction, and the lower chip filling layer may cover the plurality of chip bonding members.

According to some example embodiments of the present disclosure to address the above-described technical aspects, the forming the lower heat dissipation filling layer may further include forming a lower heat dissipation filling layer so that an upper surface of the lower heat dissipation filling layer formed in a gap region has a concave curved surface.

According to some example embodiments of the present disclosure to address the above-described technical aspects, a method of manufacturing a semiconductor package may include: forming a first redistribution structure; forming an interconnect structure on the first redistribution structure; mounting a first semiconductor chip structure on the first redistribution structure; forming a first encapsulant covering the interconnect structure and the first semiconductor chip structure; forming a second redistribution structure on the interconnect structure, the first semiconductor chip structure and the first encapsulant; mounting a heat dissipation member on the second redistribution structure; mounting a second semiconductor chip structure spaced apart from the heat dissipation member on the second redistribution structure in a first direction; and forming a filling layer to fill a lower heat dissipation space formed between the second redistribution structure and the heat dissipation member, a gap region formed between the heat dissipation member and the second semiconductor chip structure, and a lower chip space formed between the second redistribution structure and the second semiconductor chip structure.

According to some example embodiments of the present disclosure to address the above-described technical aspects, the mounting a heat dissipation member may further include forming a plurality of heat dissipation bonding members disposed below the heat dissipation member on the second redistribution structure and spaced apart from each other in the first direction, and the filling layer may cover the plurality of heat dissipation bonding members.

According to some example embodiments of the present disclosure to address the above-described technical aspects, the mounting a second semiconductor chip structure may further include forming a plurality of chip bonding members disposed below the second semiconductor chip structure on the second redistribution structure and spaced apart from each other in the first direction, and the filling layer may cover the plurality of chip bonding members.

According to some example embodiments of the present disclosure to address the above-described technical aspects, the forming a filling layer may further include forming a filling layer so that an upper surface of the filling layer formed in a gap region has a concave curved surface.

According to some example embodiments of the present disclosure to address the above-described technical aspects, the method of manufacturing a semiconductor package may further include forming an external connection bump disposed below the first redistribution structure before mounting the heat dissipation member.

According to some example embodiments of the present disclosure, to address above-described technical aspects, a method of manufacturing a semiconductor package may include: mounting a first semiconductor chip structure on a first redistribution structure; forming a second redistribution structure on first semiconductor chip structure; forming a second semiconductor chip structure and a heat dissipation member spaced apart from each other on the second redistribution structure; forming a first filling layer between the second redistribution structure and the second semiconductor chip structure; and forming a gap filling layer between the second semiconductor chip structure and the heat dissipation member. A material of the first filling layer may be different from a material of the gap filling layer.

In some embodiment, the first filling layer may include a first resin-based material, and the gap filling layer may include a silicone-based adhesive material.

In some embodiments, an upper surface of the gap filling layer may have a concave curved surface.

In some embodiments, a plurality of first bonding members may be formed below the second semiconductor chip structure, wherein the plurality of first bonding members may be formed on the second redistribution structure and spaced apart from each other in a first direction. A plurality of second bonding members may be formed below the heat dissipation member. The plurality of second bonding members may be on the second redistribution structure and spaced apart from each other in the first direction. A second filling layer may be formed between the second redistribution structure and the heat dissipation member.

In some embodiments, the heat dissipation member may include silicon (Si).

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The present disclosure is not limited to the above-described embodiments and the accompanying drawings but is defined by the appended claims. In addition, various modifications and modifications may be made within an equivalent scope of the technical idea of the present disclosure and the scope of claims to be described below by a person skilled in the technical field to which this disclosure belongs.

What is claimed is:

1. A semiconductor package, comprising:
a first redistribution structure;
a first semiconductor chip structure on the first redistribution structure;
a second redistribution structure on the first semiconductor chip structure;
a second semiconductor chip structure on the second redistribution structure;
a first filling layer between the second redistribution structure and the second semiconductor chip structure;
a heat dissipation member on the second redistribution structure, wherein the heat dissipation member is spaced apart from the second semiconductor chip structure in a first direction; and
a gap filling layer between the second semiconductor chip structure and the heat dissipation member,
wherein a material of the first filling layer is different from a material of the gap filling layer.

2. The semiconductor package of claim 1, wherein
the first filling layer includes a first resin-based material, and
the gap filling layer includes a silicone-based adhesive material.

3. The semiconductor package of claim 2, wherein the silicone-based adhesive material includes at least one of acetoxy-based silicone, alkoxy-based silicone, oxime-based silicone, amino-based silicone, silicone resin, silicone rubber, silylated polymer (SMP), or polydimethylsiloxane (PDMS).

4. The semiconductor package of claim 1, wherein the gap filling layer is in contact with an upper surface of the second redistribution structure.

5. The semiconductor package of claim 1, wherein
the gap filling layer is in contact with a side surface of the heat dissipation member,
a height of the gap filling layer in a second direction is less than a length in the second direction from an upper surface of the heat dissipation member to an upper surface of the second redistribution structure, and
the second direction intersects the first direction.

6. The semiconductor package of claim 1, wherein an upper surface of the gap filling layer has a concave curved surface.

7. The semiconductor package of claim 1, further comprising:
a plurality of first bonding members below the second semiconductor chip structure, wherein the plurality of first bonding members are on the second redistribution structure and spaced apart from each other in the first direction;
a plurality of second bonding members below the heat dissipation member, wherein the plurality of second bonding members are on the second redistribution structure and spaced apart from each other in the first direction; and
a second filling layer between the second redistribution structure and the heat dissipation member.

8. The semiconductor package of claim 7, wherein
the first filling layer covers the plurality of first bonding members, and
the second filling layer covers the plurality of second bonding members.

9. The semiconductor package of claim 7, wherein
the second filling layer includes at least one of a first resin-based material or a heat transfer material,
the heat transfer material has a higher thermal conductivity than the first resin-based material, and
the heat transfer material includes at least one of a non-resin-based material or a second resin-based material, and
the second resin-based material includes a different material from the first resin-based material.

10. The semiconductor package of claim 7, wherein the second filling layer and the plurality of second bonding members includes different materials.

11. The semiconductor package of claim 1, wherein the heat dissipation member includes silicon (Si).

12. A semiconductor package, comprising:
a first redistribution structure including a first insulating layer and a first redistribution layer in the first insulating layer;
a first semiconductor package on the first redistribution structure and including a first semiconductor chip structure and a second redistribution structure on the first semiconductor chip structure;
a second semiconductor package on the second redistribution structure and including a second semiconductor chip structure;
a heat dissipation member on the second redistribution structure and spaced apart from the second semiconductor package in a first direction;
a gap filling layer between the second semiconductor package and the heat dissipation member;
a first bonding material layer extending from a first region of the second redistribution structure, the first bonding material layer contacting a lower surface of the heat dissipation member; and
a second bonding material layer extending from a second region of the second redistribution structure, the second bonding material layer contacting the lower surface of the heat dissipation member,
wherein an elastic modulus of the first bonding material layer is different from an elastic modulus of the second bonding material layer.

13. The semiconductor package of claim 12, wherein the elastic modulus of the first bonding material layer is greater than an elastic modulus of the second bonding material layer.

14. The semiconductor package of claim 12, wherein the second redistribution structure includes a second insulating layer and a second redistribution layer in the second insulating layer, and
the first region corresponds to the second redistribution layer, and the second region corresponds to the second insulating layer.

15. The semiconductor package of claim 12, wherein the first bonding material layer and the second bonding material layer are in contact with each other in the first direction.

16. The semiconductor package of claim 12, wherein the heat dissipation member includes silicon (Si).

17. The semiconductor package of claim 12, wherein the gap filling layer and the second bonding material layer include a same material.

18. The semiconductor package of claim 12, wherein the first bonding material layer is among a plurality of first bonding material layers spaced apart from each other in the first direction, and
the second bonding material layer fills a lower space between the plurality of first bonding material layers.

19. A semiconductor package, comprising:
a first redistribution structure including a first insulating layer and a first redistribution layer in the first insulating layer;
a first semiconductor chip structure on the first redistribution structure and including a first semiconductor chip;
an external connection bump below the first redistribution structure and connected to the first redistribution layer;
a first encapsulant on the first redistribution structure and covering the first semiconductor chip structure;
a second redistribution structure on the first encapsulant, the second redistribution structure including a second insulating layer and a second redistribution layer in the second insulating layer;
an interconnect structure penetrating through the first encapsulant and electrically connecting the first redistribution layer and the second redistribution layer;
a second semiconductor chip structure on the second redistribution structure and including a second semiconductor chip;
a second encapsulating material covering the second semiconductor chip structure;
a redistribution substrate below the second semiconductor chip structure;
a heat dissipation member on the second redistribution structure and spaced apart from the second semiconductor chip structure in a first direction;
a plurality of first bonding members below the redistribution substrate and spaced apart from each other in the first direction;
a plurality of second bonding members below the heat dissipation member and spaced apart from each other in the first direction;
a first filling layer below the redistribution substrate on the second redistribution structure and covering the plurality of first bonding members;
a second filling layer below the heat dissipation member on the second redistribution structure and covering the plurality of second bonding members; and
a gap filling layer between the second semiconductor chip structure and the heat dissipation member,
wherein a material in the gap filling layer is different from a material in the first filling layer and a material in the second filling layer, and
a material of the plurality of second bonding members is different from the material of the second filling layer.

20. The semiconductor package of claim 19, wherein the material in the gap filling layer includes a silicon-based adhesive material.
